(19) United States
(12) Patent Application Publication
(10) Pub. No.: US 2025/0076565 A1
(43) Pub. Date: Mar. 6, 2025

(54) BACKLIGHT MODULE AND DISPLAY DEVICE

(71) Applicant: HKC CORPORATION LIMITED, Shenzhen (CN)

(72) Inventors: XIAOHUI YANG, Shenzhen (CN); Haijiang YUAN, Shenzhen (CN)

(21) Appl. No.: 18/814,404

(22) Filed: Aug. 23, 2024

(30) Foreign Application Priority Data
Sep. 5, 2023 (CN) 202311132900.7

(51) Int. Cl. F21V 8/00; G06F 1/18; H01L 25/075

(52) U.S. Cl. CPC G02B 6/0083; G02B 6/0073; G02B 6/0085; G06F 1/182; H01L 25/0753

(57) ABSTRACT

A backlight module and a display device are disclosed. The backlight module includes a back plate and at least one light plate fixed onto the back plate. At least one first rivet post is disposed on a side of the light plate facing the back plate. The first rivet post penetrates the back plate and protrudes from a back side of the back plate. At least one second rivet post is disposed on the back side of the back plate. The second rivet post is arranged side by side with the first rivet post. The backlight module further includes an electrostatic assembly, which is connected to both the at least one first rivet post and the at least one second rivet post and conducts the at least one first rivet post and the at least one second rivet post with each other.

### CROSS-REFERENCE TO RELATED APPLICATIONS

This application claims the priority and benefit of Chinese patent application number 2023111329007, titled “Backlight Module and Display Device” and filed Sep. 5, 2023 with China National Intellectual Property Administration, the entire contents of which are incorporated herein by reference.

### TECHNICAL FIELD

This application relates to the field of display technology, and more particularly relates to a backlight module and a display device.

### BACKGROUND

The description provided in this section is intended for the mere purpose of providing background information related to the present application but doesn't necessarily constitute prior art.

In recent years, with the improvement of people's living standards, people's requirements for daily necessities are also getting increasingly higher. For example, displays may have shortcomings such as low brightness, small viewing angles, and unclear pattern color contrast, which have led to their slow development in the high-end product series and have also reduced people's desire to buy to a certain extent. The emergence of Mini LED (Mini Lighting-Emitting-Diode) displays in recent years has completely changed the above situation. Mini LED displays have densely arranged light sources, high-quality image quality experience, and highly layered dynamic images, all of which bring people the ultimate visual enjoyment.

However, the light plate of a Mini LED display may be fixed to the back plate using a double-sided adhesive. Since the double-sided adhesive is insulating, the static electricity on the light plate cannot be released to the back plate. Furthermore, due to the dense arrangement of light-emitting elements on the light plate, when the electrostatic protection capability of the light plate is relatively weak, the LEDs may be easily damaged by the static electricity, so that some light-emitting elements may be unable to lighten up resulting in failure thus shortening the service life of the Mini LED display.

### SUMMARY

It is therefore one purpose of this application to provide a backlight module and display device that can improve the electrostatic protection effect on the light plate and avoid the problem of failure of the light-emitting elements.

This application discloses a backlight module. The backlight module includes a back plate and at least one light plate, and the at least one light plate is fixed onto the back plate. At least one first rivet post is disposed on the side of the light plate facing the back plate. The first rivet post penetrates the back plate and protrudes from a back of the back plate. At least one second rivet post is disposed on the back of the back plate. The second rivet post is arranged side by side with the first rivet post. The backlight module further includes an electrostatic assembly. The electrostatic assembly is connected to the first rivet post and the second rivet post at the same time, so as to conduct the first rivet post and the second rivet post with each other.

In some embodiments, the electrostatic assembly includes a lower box, a top cover, a positive conductive plate, and a negative conductive plate. The lower box is made of an insulating material. The lower box defines through holes corresponding to the first rivet post and the second rivet post respectively. The top cover is made of an insulating material and is fitted with the lower box to form a sealed cavity. The positive conductive plate is arranged in the sealed cavity, fixed onto the lower box, and connected to the first rivet post. The negative conductive plate is arranged in the sealed cavity, fixed onto the lower box, and connected to the second rivet post. The positive conductive plate is electrically connected to the negative conductive plate.

In some embodiments, two first rivet posts are disposed on the light plate, and two second rivet posts are disposed on the back plate. The first rivet posts and the second rivet posts are each hollow inside to form a sleeve hole. The positive conductive plate includes a positive plate and two first rivets. The first rivets are disposed on the side of the positive plate facing the lower box, corresponding to the first rivet posts. The first rivets are inserted into the sleeve holes in the first rivet posts so as to be fixed to the first rivet posts. The negative conductive plate includes a negative plate and two second rivets. The second rivets are disposed on the side of the negative plate facing the lower box, corresponding to the second rivet posts. The second rivets are inserted into the sleeve holes in the second rivet posts so as to be fixed to the second rivet posts. The positive plate defines at least two first fixing holes, and the negative plate defines at least two second fixing holes. There are a plurality of hot rivets disposed on the side of the lower box facing the top cover. The plurality of hot rivets are respectively inserted into the first fixing holes and the second fixing holes to secure the positive conductive plate and the negative conductive plate.

In some embodiments, the electrostatic assembly includes a light-emitting assembly. One end of the light-emitting assembly is connected to the positive conductive plate, and the other end of the light-emitting assembly is connected to the negative conductive plate.

In some embodiments, the light-emitting assembly includes a conductive substrate and a plurality of light-emitting elements. The conductive substrate is a ring-shaped structure with unconnected ends. The plurality of light-emitting elements are arranged at intervals on a surface of the conductive substrate. The lower box includes a bottom plate and a fixing seat. The positive conductive plate and the negative conductive plate are arranged on the bottom plate. The fixing seat is arranged on the side of the bottom plate facing the top cover, and is arranged around the positive conductive plate and the negative conductive plate. An insertion groove is defined in the fixing seat, and the insertion groove is disposed around the positive conductive plate and the negative conductive plate. The conductive substrate is inserted into the insertion groove. One end of the conductive substrate is connected to the positive conductive plate through a first lead, and the other end of the conductive substrate is connected to the negative conductive plate through a second lead.

In some embodiments, the top cover includes a cover plate and a side plate. The side plate is arranged on the side of the cover plate facing the lower box, and the side plate is arranged around an edge of the cover plate. The end of the side plate facing away from the cover plate is fixedly connected to the bottom plate. The light-emitting elements are arranged on the side of the conductive substrate facing the side plate. The side plate defines a plurality of observation holes. The observation holes are arranged in one-to-one correspondence with the light-emitting elements.

In some embodiments, the side plate includes first annular side plate and second annular side plate. The first annular side plate is connected to the cover plate and is arranged around the edge of the cover plate. The observation holes are defined in the first annular side plate. The second annular side plate is connected to the end of the first annular side plate facing away from the cover plate and is arranged around the first annular side plate. A peripheral area is formed between the fixing seat and an edge of the bottom plate. An orthographic projection of the second annular side plate on the bottom plate coincides with the peripheral area. The second annular side plate is bonded with and fixed to the portion of the bottom plate in the peripheral area through a double-sided tape.

In some embodiments, the electrostatic assembly further includes a thermal conductive piece. The thermal conductive piece is disposed in the closed cavity and is in contact with the positive conductive plate and the conductive substrate.

In some embodiments, the thermal conductive piece is also attached to the negative conductive plate.

This application further discloses a display device. The display device includes a display panel and a backlight module as described above, where the backlight module provides backlight for the display panel.

This application has the following beneficial effects. In the present application, an electrostatic assembly is added to the backlight module, and the electrostatic assembly is connected to the first rivet post on the back of the light plate and to the second rivet post on the back of the back plate, so that a conductive path is formed between the light plate, the first rivet post, the electrostatic assembly, the second rivet post, and the back plate. In this way, when static electricity is generated on the light plate, the static electricity can be transferred to the back plate along the first rivet post, the electrostatic assembly, and the second rivet post, thus solving the problem of accumulation of static electricity on the light plate. The electrostatic protection effect on the light plate is thus improved to avoid the failure of the LEDs caused by static electricity accumulation on the light plate, thereby increasing the service life of the display product.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principle of the present application in conjunction with the text description. Apparently, the drawings in the following description merely represent some embodiments of the present disclosure, and for those having ordinary skill in the art, other drawings may also be obtained based on these drawings without investing creative efforts. A brief description of the accompanying drawings is provided as follows.

FIG. 1 is an exploded schematic diagram of a display device provided by an embodiment of the present application.

FIG. 2 is a schematic diagram of a backlight module in a first state according to an embodiment of the present application.

FIG. 3 is a schematic diagram of a backlight module in a second state according to an embodiment of the present application.

FIG. 4 is an overall schematic diagram of an electrostatic assembly provided by an embodiment of the present application.

FIG. 5 is an exploded schematic diagram of an electrostatic assembly provided by an embodiment of the present application.

FIG. 6 is a schematic view of a back of a back plate provided by an embodiment of the present application.

FIG. 6A is a schematic diagram of a second rivet post shown in FIG. 6.

FIG. 7 is a three-dimensional schematic diagram of a positive conductive plate and a negative conductive plate according to an embodiment of the present application.

FIG. 8 is a schematic plan view of a positive conductive plate and a negative conductive plate according to an embodiment of the present application.

FIG. 8A is a cross-sectional view of a first rivet shown in FIG. 8.

FIG. 9 is a schematic diagram of a lower box according to an embodiment of the present application.

FIG. 10 is an exploded schematic diagram of a lower box, a light-emitting element, a positive conductive plate, and a negative conductive plate according to an embodiment of the present application.

FIG. 11 is a cross-sectional view after the lower box and the light-emitting elements are fixed together according to an embodiment of the present application.

FIG. 12 is an overall schematic diagram of a lower box, a light-emitting element, a positive conductive plate, and a negative conductive plate according to an embodiment of the present application.

FIG. 13 is a schematic diagram of a top cover according to an embodiment of the present application.

FIG. 13A is a schematic cross-sectional view of an observation hole shown in FIG. 13.

FIG. 14 is an exploded schematic diagram of another electrostatic assembly according to an embodiment of the present application.

FIG. 15 is a schematic diagram of an electrostatic assembly including a thermal conductive piece according to an embodiment of the present application.

In the drawing: 10, display device; 20, backlight module; 30, display panel; 100, back plate; 110, second rivet post; 200, electrostatic assembly; 210, lower box; 211, hot rivet; 212, through hole; 213, bottom plate; 214, fixing seat; 215, insertion groove; 216, silicone; 220, top cover; 221, cover plate; 222, side plate; 223, first annular side plate; 224, second annular side plate; 225, observation hole; 226, double-sided tape; 230, positive conductive plate; 231, positive plate; 232, first rivet; 233, first fixing hole; 234, first lead; 240, negative conductive plate; 241, negative plate; 242, second rivet; 243, second fixing hole; 244, second lead; 250, light-emitting element; 251, conductive substrate; 252, light-emitting element; 260, thermal conductive piece; 300, double-sided adhesive; 400, light plate; 410, first rivet post; 500, sealant frame; 600, diffusion plate assembly; 700, optical film; 800, foam glue.

### DETAILED DESCRIPTION OF EMBODIMENTS

It should be understood that the terms used herein, the specific structures and function details disclosed herein are intended for the mere purposes of describing specific embodiments and are representative. However, this application may be implemented in many alternative forms and should not be construed as being limited to the embodiments set forth herein.

Furthermore, as used herein, terms “mounted on”, “connected to”, “coupled to”, “connected with”, and “coupled with” should be understood in a broad sense unless otherwise specified and defined. For example, they may indicate a fixed connection, a detachable connection, or an integral connection. They may denote a mechanical connection, or an electrical connection. They may denote a direct connection, a connection through an intermediate, or an internal connection between two elements. For those of ordinary skill in the art, the specific meanings of the above terms as used in the present application can be understood depending on specific contexts.

Hereinafter this application will be described in further detail with reference to the accompanying drawings and some optional embodiments.

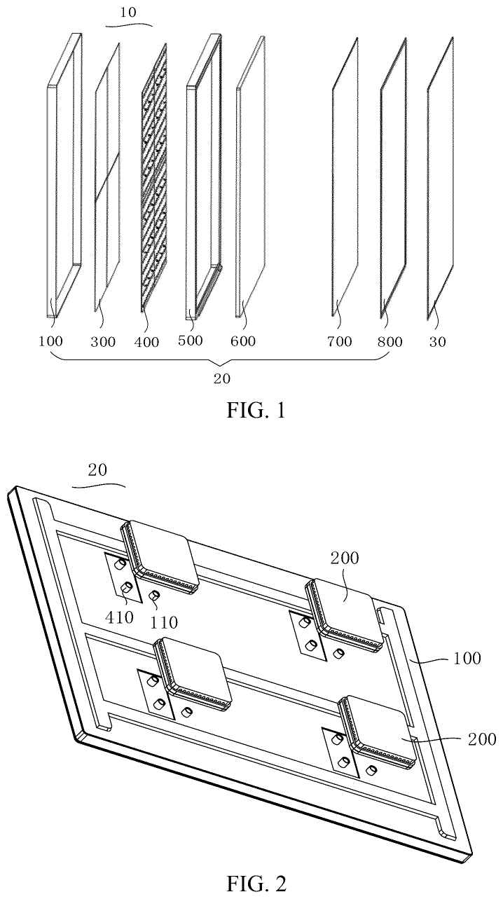

FIG. 1 is a schematic diagram of a display device according to an embodiment of the present application. As illustrated in FIG. 1, an embodiment of the present application provides a display device 10. The display device 10 includes a display panel 30 and a backlight module 20. The backlight module 20 uses mini LED backlight technology to provide backlight for the display panel 30. The backlight module 20 includes a back plate 100, a double-sided adhesive 300, a light plate 400, a sealant frame 500, a diffusion plate assembly 600, an optical film 700, and a foam glue 800. There is at least one light plate 400, which is bonded and fixed onto the back plate 100 through the double-sided adhesive 300. The sealant frame 500 is fixed onto the back plate 100 and is arranged around all the light plates 400. The optical film 700 and the diffusion plate assembly 600 are stacked on the sealant frame 500 in sequence. The display panel 30 is fixed onto the sealant frame 500 through the foam glue 800.

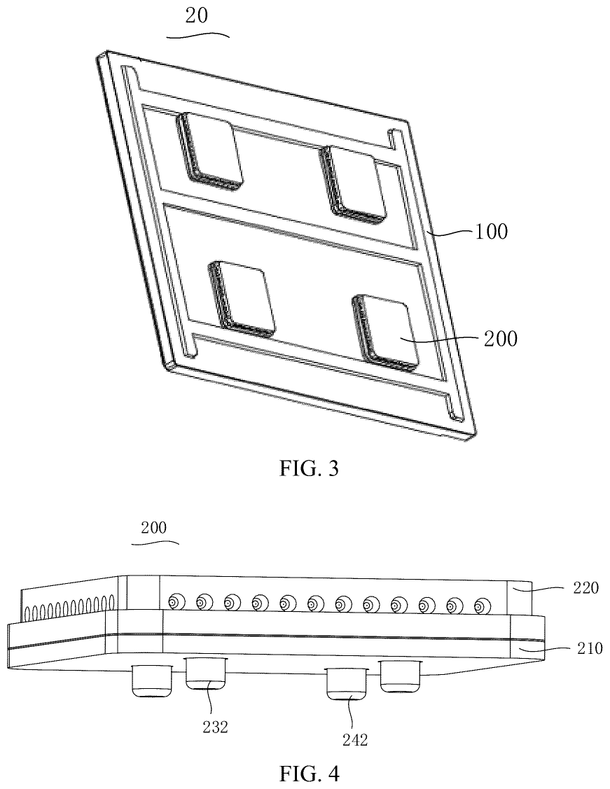

FIG. 2 is a schematic diagram of a backlight module in a first state according to an embodiment of the present application. FIG. 3 is a schematic diagram of a backlight module in a second state according to an embodiment of the present application. The first state is a state when the electrostatic assembly 200 and the back plate 100 are separated, and the second state is a state when the electrostatic assembly 200 and the back plate 100 are secured together. As illustrated in FIG. 2 and FIG. 3, an embodiment of the present application provides a backlight module 20. At least one first rivet post 410 is disposed on a side of the light plate 400 facing the back plate 100. The first rivet post 410 penetrates the back plate 100 and protrudes from a back surface of the back plate 100. At least one second rivet post 110 is disposed on the back of the back plate 100. The second rivet post 110 is arranged side by side with the first rivet post 410. The backlight module 20 further includes an electrostatic assembly 200. The electrostatic assembly 200 is connected to both the first rivet post 410 and the second rivet post 110, and conducts the first rivet post 410 and the second rivet post 110 electrically.

It can be understood that the light plate 400 is disposed on the front side of the back plate 100 and the electrostatic assembly 200 is disposed on the back side of the back plate 100. The first rivet post 410 is disposed on the back side of the light plate 400. The first rivet post 410 passes through the via hole in the double-sided adhesive 300 and the back plate 100 and further protrudes from the back side of the back plate 100, so that there is a height difference between the end of the first rivet post 410 and the back surface of the back plate 100. Furthermore, both the first rivet post 410 and the second rivet post 110 are made of a metal material. There is a conductive structure inside the electrostatic assembly 200 that can connect the first rivet post 410 and the second rivet post 110 electrically, or the entire electrostatic assembly 200 may be made of a conductive material, so that static electricity can be transferred from the light plate 400 to the back plate 100.

In this embodiment of the present application, an electrostatic assembly 200 is added to the backlight module 20, and the electrostatic assembly 200 is connected to the first rivet post 410 on the back of the light plate 400 and to the second rivet post 110 on the back of the back plate 100, so that a conductive path is formed between the light plate 400, the first rivet post 410, the electrostatic assembly 200, the second rivet post 110, and the back plate 100. In this way, when static electricity is generated on the light plate 400, the static electricity can be transferred to the back plate 100 along the first rivet post 410, the electrostatic assembly 200, and the second rivet post 110, thus solving the problem of accumulation of static electricity on the light plate 400. The electrostatic protection effect on the light plate 400 is thus improved to avoid the failure of the LEDs caused by static electricity accumulation on the light plate 400, thereby increasing the service life of the display product.

In the backlight module 20, the plurality of electrostatic assemblies 200 and the plurality of light plates 400 are in one-to-one correspondence in quantities. When multiple light plates 400 are disposed on the back plate 100, then multiple electrostatic assemblies 200 are installed on the bottom of the back plate 100. The multiple electrostatic assemblies 200 are connected to the light plates 400 in one-to-one correspondence. Each electrostatic assembly 200 releases the static electricity for the corresponding light plate 400 to avoid mutual interference, and at the same time, it can also accelerate the electrostatic discharge effect on the respective light plate 400.

Furthermore, in the backlight module 20, the electrostatic assembly 200 and the back plate 100 may be detachably connected. For example, the electrostatic assembly 200 may be plugged directly into the first rivet post 410 and the second rivet post 110. In this way, the number of the electrostatic assemblies 200 installed on the back plate 100 may be reduced as needed, or even the electrostatic assemblies 200 may only be used for testing the static electricity on the light plate 400. When the test results meet the standards, all the electrostatic assemblies 200 may be disassembled, so that the backlight module 20 can meet a variety of usage requirements.

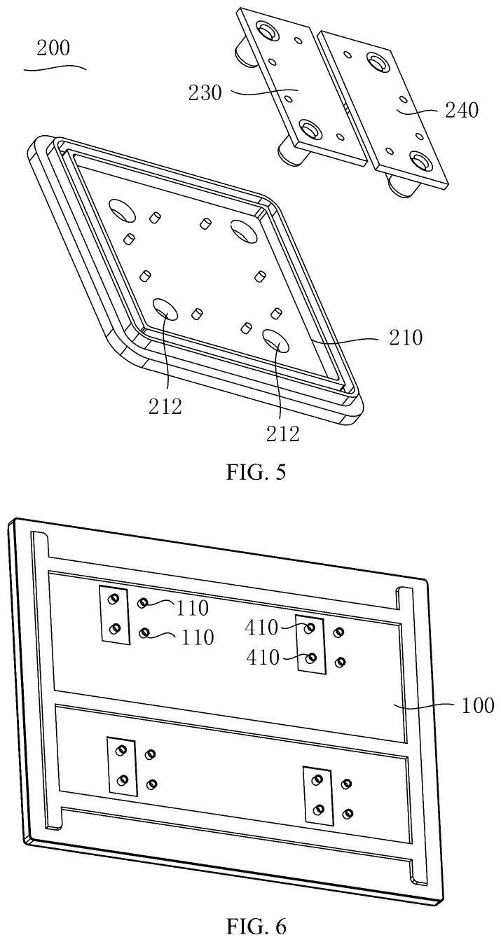

As one of the designs of the electrostatic assembly 200, as illustrated in FIGS. 4 and 5, the electrostatic assembly 200 includes a lower box 210, a top cover 220, a positive conductive plate 230, and a negative conductive plate 240. The lower box 210 is made of an insulating material, and the lower box 210 defines through holes 212 corresponding to the first rivet post 410 and the second rivet post 110 respectively. The top cover 220 is made of an insulating material and is fitted with the lower box 210 to form a sealed cavity. The positive conductive plate 230 is arranged in the sealed cavity, fixed onto the lower box 210, and connected to the first rivet post 410. The negative conductive plate 240 is arranged in the sealed cavity, fixed onto the lower box 210, and connected to the second rivet post 110. The positive conductive plate 230 is connected with the negative conductive plate 240.

In the embodiment of the present application, both the positive conductive plate 230 and the negative conductive plate 240 are made of a conductive material, and the entire body may be made of a metallic copper material. When static electricity is generated on the light plate 400, the static electricity may be transferred to the back plate 100 through the first rivet post 410, the positive conductive plate 230, the negative conductive plate 240, and the second rivet post 110. The electrostatic box design in which the top cover 220 and the lower box 210 form a box wrapping the positive conductive plate 230 and the negative conductive plate 240 can avoid the exposure of static electricity which may cause the risk of leakage of the display product. Furthermore, the positive conductive plate 230 is connected to the first rivet post 410, and the negative conductive plate 240 is connected to the second rivet post 110, thereby achieving the fixation of the electrostatic box. This method improves the stability of the contact between the positive conductive plate 230 and the negative conductive plate 240 with the respective rivet posts, thereby effectively ensuring the electrostatic conduction effect of the electrostatic assembly 200.

In other implementation designs, the lower box 210 may be directly fixed onto the back of the back plate 100 through a snap-fit, screw connection, etc, and then a wire may be used to directly wrap around the first rivet post 410 and the second rivet post 110, which can also conduct static electricity on the light plate 400 to the back plate 100. Alternatively, the positive conductive plate 230 and the negative conductive plate 240 may also be made into an integrated structure. Of course, the electrostatic assembly 200 may also adopt other designs, which may be adopted depending on the actual situation. As long as the static electricity on the light plate 400 can be conducted to the back plate 100, it shall fall in the scope of protection of this application.

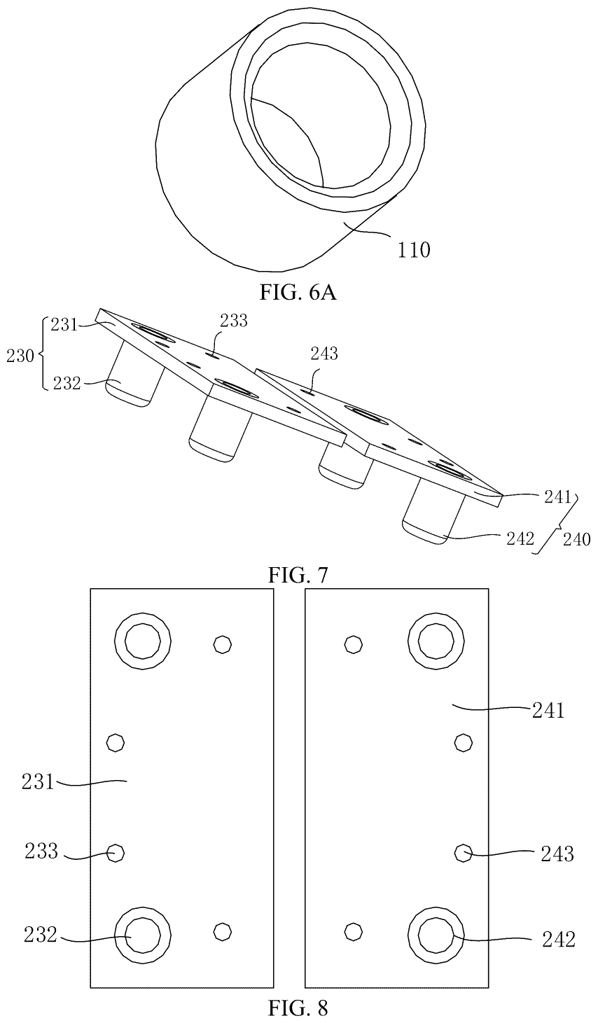

Specifically, as illustrated in FIG. 6 and FIG. 6A, two first rivet posts 410 are disposed on the light plate 400, and the two first rivet posts 410 are arranged in a column. Two second rivet post 110 are disposed on the back plate 100, and the two second rivet post 110 are arranged in a column. The two first rivet posts 410 and the two second rivet posts 110 form a square structure. In addition, the length of the first rivet post 410 is greater than the length of the second rivet post 110, so that the ends of the first rivet post 410 and the second rivet post 110 facing away from the back plate 100 are flush. The first rivet post 410 and the second rivet post 110 are each hollow inside to form a sleeve hole. An opening of each sleeve hole faces the electrostatic assembly 200. A cross-section of the sleeve hole may be circular, square or in other shapes, which are not limited here.

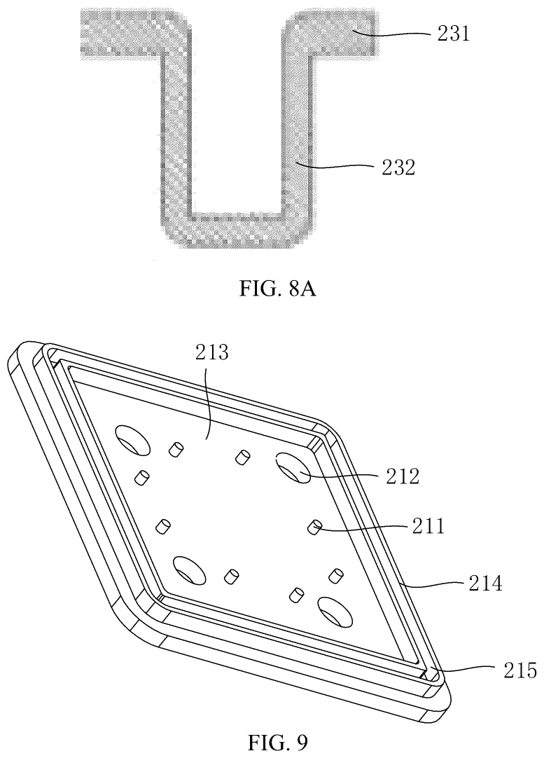

As illustrated in FIGS. 7 and 8, in the lower box 210, the positive conductive plate 230 and the negative conductive plate 240 are arranged side by side and symmetrically. The positive conductive plate 230 includes a positive plate 231 and two first rivets 232. The first rivets 232 are arranged on the side of the positive plate 231 facing the lower box 210, corresponding to the first rivet posts 410. The first rivets 232 are inserted into the sleeve holes of the respective first rivet posts 410 so as to be fixed to the first rivet posts 410. The negative conductive plate 240 includes a negative plate 241 and two second rivets 242. The second rivets 242 are arranged on the side of the negative plate 241 facing the lower box 210, corresponding to the second rivet posts 110. The second rivets 242 are inserted into the sleeve holes of the respective second rivet posts 110 so as to be fixed to the second rivet posts 110. The positive plate 231 and the negative plate 241 are connected together. Of course, the number of each of the first rivet posts 410, the second rivet posts 110, the first rivets 232, and the second rivets 242 can be more than two, and the corresponding design may be adopted as needed.

As illustrated in FIG. 8A, the first rivet 232 and the second rivet 242 may adopt hollow copper tubes. When the electrostatic assembly 200 is installed on the back plate 100, the first rivet 232 may be aligned with the first rivet post 410, the second rivet 242 may be aligned with the second rivet post 110, and then the first rivet 232 and the second rivet 242 may be inserted into the first rivet post 410 and second rivet post 110 respectively, thereby utilizing the friction and squeezing force between the rivets and the rivet posts to achieve fixation of the electrostatic assembly 200. Of course, the first rivet 232 and the second rivet 242 may also be solid rod-shaped structures, which can be designed accordingly as needed.

As illustrated in FIG. 7, FIG. 8 and FIG. 9, the positive plate 231 defines four first fixing holes 233, and the negative plate 241 defines four second fixing holes 243. Eight hot rivets 211 are disposed on the side of the lower box 210 facing the top cover 220. Each hot rivet 211 has a slightly larger top diameter relative to its lower part. The eight hot rivets 211 are respectively inserted into the four first fixing holes 233 and the four second fixing holes 243 to fix the positive conductive plate 230 and the negative conductive plate 240 to each other.

Specifically, in the square area formed by the positive plate 231 and the negative plate 241, the two first rivets 232 and the two second rivets 242 are respectively located at the four corners of this area, and the eight fixing holes are arranged in such a manner that there are two fixing holes on each side of the square area. Through the above arrangement design, the stability of the positive conductive plate 230 and the negative conductive plate 240 can be further improved. Furthermore, the distance between the first rivet 232 and the second rivet 242 is relatively large, and the static electricity passes through a relative large distance on the positive plate 231 and the negative plate 241, which is also conducive to increasing the consumption of the static electricity. Of course, the number of each of the fixing holes, the rivets, the rivet posts, and the hot rivets 211 may also be reasonably arranged according to the actual structural sizes, as long as it is not less than two.

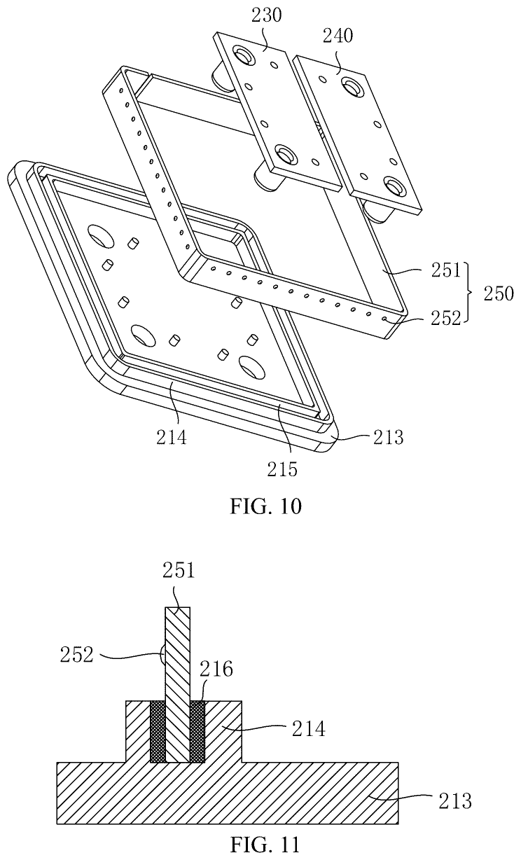

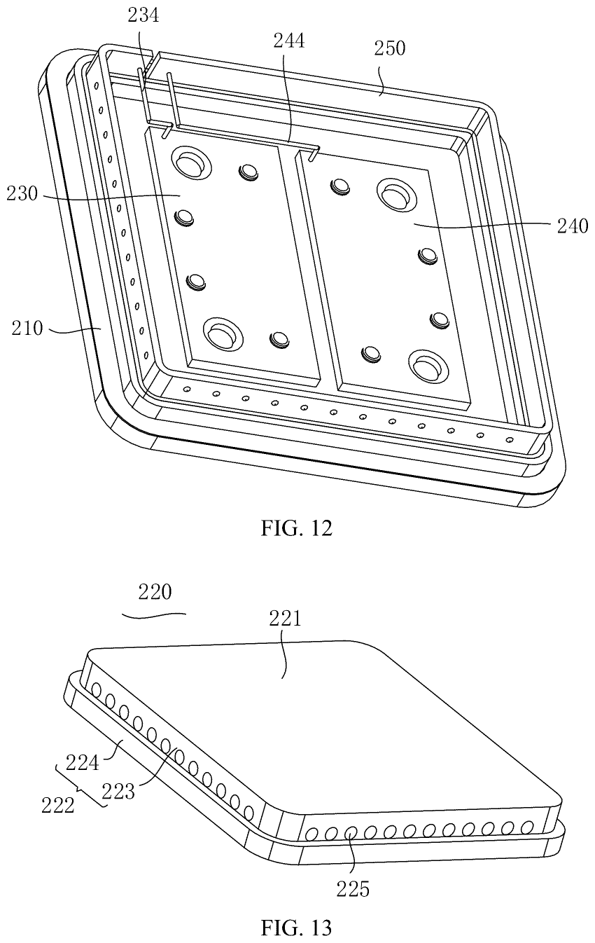

Further, as illustrated in FIG. 9, FIG. 10, FIG. 11, and FIG. 12, the electrostatic assembly 200 includes a light-emitting assembly 250. One end of the light-emitting assembly 250 is connected to the positive conductive plate 230, and the other end of the light-emitting assembly 250 is connected to the negative conductive plate 240. At this time, the static electricity on the light plate 400 is first consumed by the light-emitting assembly 250, and the remaining static electricity is then conducted to the back plate 100, so that the static electricity on the light plate 400 is consumed faster and more completely.

Specifically, the light-emitting assembly 250 includes a conductive substrate 251 and a plurality of light-emitting elements 252. The conductive substrate 251 is made of a conductive material such as copper or aluminum, which forms a ring-shaped structure with unconnected ends. The plurality of light-emitting elements 252 arranged at intervals on the surface of the conductive substrate and are electrically connected to the conductive substrate 251. Specifically, the conductive substrate 251 is a square ring-shaped structure formed by bending a strip of copper sheet or other metal sheet multiple times. Of course, the conductive substrate 251 may also be formed into a corresponding shape according to the required shape of the electrostatic assembly 200. After the conductive substrate 251 is bent and formed into shape, the two ends are not in contact, leaving a certain gap to prevent the conductive substrate 251 from forming a loop structure. Finally, the multiple light-emitting elements 252 may be welded to an outer side wall of the conductive substrate 251 in sequence.

Correspondingly, the lower box 210 includes a bottom plate 213 and a fixing seat 214. The positive conductive plate 230 and the negative conductive plate 240 are disposed on the bottom plate 213. The hot rivet 211 is also arranged on the bottom plate 213. The fixing seat 214 is disposed on the side of the bottom plate 213 facing the top cover 220 and surrounds the positive conductive plate 230 and the negative conductive plate 240. The fixing seat 214 defines an insertion groove 215. An opening of the insertion groove 215 faces upward and the insertion groove 215 is arranged around the positive conductive plate 230 and the negative conductive plate 240. The conductive substrate 251 is inserted into the insertion groove 215. Furthermore, one end of the conductive substrate 251 is connected to the positive conductive plate 230 through a first lead 234, and the other end of the conductive substrate 251 is connected to the negative conductive plate 240 through a second lead 244.

At this time, the conductive substrate 251 not only serves to connect all light-emitting elements 252 together, but also serves to connect the positive conductive plate 230 and the negative conductive plate 240 together. After the conductive substrate 251 is inserted into the insertion groove 215, the light-emitting elements 252 are exposed outside the insertion groove 215 and are distributed on the four sides of the conductive substrate 251 in a direction of facing away from the positive conductive plate 230 and the negative conductive plate 240. Through the above design, when static electricity is generated on the light plate 400, the static current passes through the light-emitting assembly 250, causing the light-emitting element 252 to emit light. This not only increases the consumption of static electricity, but also allows to determine the severity of static electricity generated on the light plate 400 by observing the luminescence of the light-emitting elements 252, so as to better protect the display product. Furthermore, static electricity needs to pass through the entire length of the conductive substrate 251, the first lead 234, and the second lead 244 in the electrostatic assembly 200, so that the path that static electricity takes is even longer. Since the materials of the conductive substrate 251, the first lead 234, and the second lead 244 themselves consume static electricity, the consumption of static electricity on the light plate 400 can be further increased.

Furthermore, the insertion groove 215 is also filled with a silicone 216. The conductive substrate 251 is inserted into the insertion groove 215, and the silicone 216 squeezes the conductive substrate 251, so that the conductive substrate 251 has a desirable stability, and it can also improve the sealing between the conductive substrate 251 and the lower box 210.

As illustrated in FIG. 12, the distance between the ends of conductive substrate 251 is relatively small. The light-emitting elements 252 are evenly distributed on each side of the conductive substrate 251, thereby increasing the number of light-emitting elements 252 on the conductive substrate 251 and increasing the consumption of static electricity. Furthermore, the inspector can see the luminous effect of the light-emitting elements 252 from every direction of the electrostatic assembly 200, making it convenient for observation. As for the first lead 234 and the second lead 244, copper wires or other conductive wires may be used. Both ends of each of the first lead 234 and the second lead 244 may be connected to the conductive substrate 251 and the corresponding conductive plate by welding respectively.

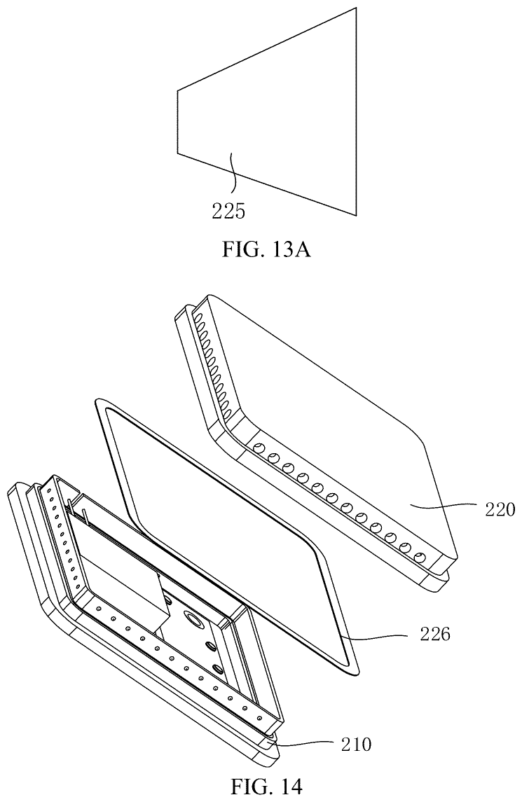

Furthermore, as illustrated in FIG. 4 and FIG. 13, the top cover 220 includes a cover plate 221 and a side plate 222. The side plate 222 is disposed on the side of the cover plate 221 facing the lower box 210, and the side plate 222 is disposed around an edge of the cover plate 221. One end of the side plate 222 facing away from the cover plate 221 is fixedly connected to the bottom plate 213. The light-emitting elements 252 are disposed on the side of the conductive substrate 251 facing the side plate 222. The side plate 222 defines a plurality of observation holes 225. The observation holes 225 are arranged in one-to-one correspondence with the light-emitting elements 252. First, the structure of the top cover 220 improves the stability of the internal structure of the electrostatic assembly 200 thus preventing the light-emitting assembly 250, the positive conductive plate 230, and the negative conductive plate 240 from falling off. Second, it can prevent static electricity from being exposed. Third, the top cover 220, the lower box 210, and the conductive substrate 251 form a closed space to prevent external stains and water vapor from entering and affecting the electrostatic conduction effect.

Furthermore, a side wall of the top cover 220 adopts a step structure. Specifically, the side plate 222 includes a first annular side plate 223 and a second annular side plate 224 that are connected to each other. The first annular side plate 223 is connected to the cover plate 221 and is arranged around an edge of the cover plate 221. The observation holes 225 are defined in the first annular side plate 223. The second annular side plate 224 is connected to an end of the first annular side plate 223 facing away from the cover plate 221 and is arranged around the first annular side plate 223.

A peripheral area is formed between the fixing seat 214 and an edge of the bottom plate 213. An orthographic projection of the second annular side plate 224 on the bottom plate 213 coincides with the peripheral area, so that the edge of the second annular side plate 224 is just aligned with the edge of the bottom plate 213.

As illustrated in FIG. 14, the second annular side plate 224 is bonded with and fixed to the portion of the bottom plate 213 in the peripheral area through a double-sided tape 226. The double-sided tape 226 is annular and also coincides with the peripheral area to seal the interface between the second annular side plate 224 and the bottom plate 213 to achieve sealing of the entire box.

As illustrated in FIG. 13A, as for the design of the observation hole 225, an embodiment of the present application adopts a flared and trumpet-shaped design, so that the cross section of the observation hole 225 gradually increases in the direction from the inside to the outside of the electrostatic assembly 200. Through the above design, it is more convenient to observe the brightness of the light-emitting elements 252, and the light-emitting elements 252 will not penetrate into the observation holes 225, which is beneficial to the protection of the light-emitting elements 252.

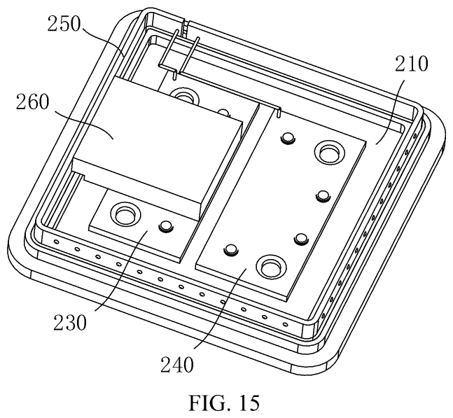

As illustrated in FIG. 15, the electrostatic assembly 200 further includes a thermal conductive piece 260. The thermal conductive piece 260 uses thermal conductive materials such as a thermal conductive silicone 216, a thermal conductive tape, a thermal conductive metal, etc. The thermal conductive piece 260 is disposed in the sealed cavity and contacts both the positive conductive plate 230 and the conductive substrate 251. In this case, when the light plate 400 generates heat, the heat on the light plate 400 can quickly diffuse to the outside through the first rivet post 410, the positive conductive plate 230, the thermal conductive piece 260, and the conductive substrate 251, so that the electrostatic assembly 200 can not only protect the light plate 400 from static electricity, but also effectively dissipate heat, further improve the performance of the display device 10 and increase the service life of the display device 10.

Further, the thermal conductive piece 260 is also filled in the closed cavity formed by the top cover 220 and the lower box 210, so that the thermal conductive piece 260 is not only attached to the positive conductive plate 230 and the conductive substrate 251, but also attached to the negative conductive plate 240. In this case, the thermal conductive piece 260 can also transfer the heat on the light plate 400 to the back plate 100 through the negative conductive plate 240, thereby further improving the heat dissipation effect of the light plate 400.

It can be understood that those having ordinary skill in the art may also make adaptive adjustments to the backlight module 20 disclosed in the embodiments of the present application depending on actual conditions, or add or delete some structures, without affecting the protection effect of the present application.

The foregoing description is merely a further detailed description of the present application with reference to some illustrative embodiments, and the specific implementations of the present application are not to be construed to be limited to these illustrative embodiments. For those having ordinary skill in the technical field to which this application pertains, numerous simple deductions or substitutions may be made without departing from the concept of this application, which shall all be regarded as falling in the scope of protection of this application.

What is claimed is:

1. A backlight module, comprising:
a back plate;
at least one light plate, fixed onto the back plate; wherein there is disposed at least one first rivet post on a side of the at least one light plate facing the back plate, wherein the at least one first rivet post penetrates the back plate and protrudes from a back side of the back plate; wherein there is disposed at least one second rivet post on the back side of the back plate, wherein the at least one second rivet post is arranged side by side with the at least one first rivet post; and
at least one electrostatic assembly, which is connected to both the at least one first rivet post and the at least one second rivet post, and conducts the at least one first rivet post and the at least one second rivet post with each other.

2. The backlight module as recited in claim 1, wherein the electrostatic assembly comprises:
a lower box, made of an insulating material, wherein there is defined in the lower box a through hole corresponding to each of the at least one first rivet post and the at least one second rivet post;
a top cover, made of an insulating material and fitted with the lower box to form a sealed cavity;
a positive conductive plate, which is arranged in the sealed cavity, fixed onto the lower box, and connected to the at least one first rivet post; and
a negative conductive plate, which is arranged in the sealed cavity, fixed onto the lower box, and connected to the at least one second rivet post, wherein the positive conductive plate is electrically connected with the negative conductive plate.

3. The backlight module as recited in claim 2, wherein there is disposed two first rivet posts on each of the at least one light plate, and two second rivet posts on the back plate;
wherein the two first rivet posts and the two second rivet posts are each hollowed inside to form a respective sleeve hole;
wherein the positive conductive plate comprises a positive plate and two first rivets, the two first rivets being disposed on a side of the positive plate facing the lower box and are disposed corresponding to the two first rivet posts respectively; wherein the two first rivets are inserted into the respective sleeve holes of the two first rivet posts so as to be fixed to the two first rivet posts respectively;
wherein the negative conductive plate comprises a negative plate and two second rivets, wherein the two second rivets are disposed on a side of the negative plate facing the lower box and are disposed corresponding to the two second rivet posts respectively; wherein the two second rivets are inserted into the respective sleeve holes of the two second rivet posts so as to be fixed to the two second rivet posts respectively.

4. The backlight module as recited in claim 3, wherein the two first rivet posts and the two second rivet posts jointly form a square structure.

5. The backlight module as recited in claim 3, wherein a length of each of the two first rivet posts is greater than a length of each of the two second rivet posts, and wherein an end of each of the first rivet posts and an end of each of the second rivet posts facing away from the back plate are flush with each other.

6. The backlight module as recited in claim 3, wherein the two first rivets and the two second rivets are each implemented as a hollow copper tube.

7. The backlight module as recited in claim 3, wherein there is defined at least two first fixing holes in the positive plate, and at least two second fixing holes in the negative plate;
wherein there is disposed a plurality of hot rivets on a side of the lower box facing the top cover; wherein the plurality of hot rivets are respectively inserted into the at least two first fixing holes and the at least two second fixing holes to secure the positive conductive plate and the negative conductive plate.

8. The backlight module as recited in claim 7, wherein the positive plate defines four first fixing holes, and wherein the negative plate defines four second fixing holes; wherein there is disposed a number of eight hot rivets on the side of the lower box facing the top cover, and wherein the eight hot rivets are respectively inserted into the four first fixing holes and the four second fixing holes.

9. The backlight module as recited in claim 2, wherein the positive conductive plate and the negative conductive plate are arranged side by side and symmetrically inside the electrostatic assembly.

10. The backlight module as recited in claim 2, wherein the electrostatic assembly comprises a light-emitting assembly, wherein one end of the light-emitting assembly is connected to the positive conductive plate, and wherein another end of the light-emitting assembly is connected to the negative conductive plate.

11. The backlight module as recited in claim 10, wherein the light-emitting assembly comprises a conductive substrate and a plurality of light-emitting elements, wherein the conductive substrate is a ring-shaped structure with unconnected ends, and wherein the plurality of light-emitting elements are arranged at intervals on a surface of the conductive substrate;
wherein the lower box comprises a bottom plate and a fixing seat, wherein the positive conductive plate and the negative conductive plate are arranged on the bottom plate; wherein the fixing seat is arranged on a side of the bottom plate facing the top cover, and is disposed around the positive conductive plate and the negative conductive plate; wherein there is defined an insertion groove in the fixing seat, and wherein the insertion groove is disposed around the positive conductive plate and the negative conductive plate;
wherein the conductive substrate is inserted into the insertion groove, wherein one end of the conductive substrate is connected to the positive conductive plate through a first lead, and wherein another end of the conductive substrate is connected to the negative conductive plate through a second lead.

12. The backlight module as recited in claim 11, wherein the top cover comprises a cover plate and a side plate, the side plate being disposed on a side of the cover plate facing the lower box; wherein the side plate is arranged around an edge of the cover plate, and wherein an end of the side plate facing away from the cover plate is fixedly connected to the bottom plate;
wherein the plurality of light-emitting elements are arranged on a side of the conductive substrate facing the side plate, wherein the side plate defines a plurality of observation holes, and wherein the plurality of observation holes are disposed in one-to-one correspondence with the plurality of light-emitting elements.

13. The backlight module as recited in claim 12, wherein the side plate comprises a first annular side plate and a second annular side plate, wherein the first annular side plate is connected to the cover plate and is arranged around the edge of the cover plate; wherein the plurality of observation holes are defined in the first annular side plate; wherein the second annular side plate is connected to an end of the first annular side plate facing away from the cover plate, and is disposed around the first annular side plate; wherein there is defined a peripheral area between the fixing seat and an edge of the bottom plate; wherein an orthographic projection of the second annular side plate on the bottom plate coincides with the peripheral area; wherein the second annular side plate is bonded with and fixed to the portion of the bottom plate in the peripheral area through a double-sided tape.

14. The backlight module as recited in claim 12, wherein a cross section of each of the plurality of observation holes gradually increases in a direction from an inside to an outside of the electrostatic assembly.

15. The backlight module as recited in claim 11, wherein the electrostatic assembly further comprises a thermal conductive piece, which is disposed in the closed cavity and is attached to both the positive conductive plate and the conductive substrate.

16. The backlight module as recited in claim 15, wherein the thermal conductive piece is further in contact with the negative conductive plate.

17. The backlight module as recited in claim 1, wherein a number of the at least one electrostatic assembly is in one-to-one correspondence with a number of the light plates, and wherein the electrostatic assemblies and the plurality of light plates are connected in one-to-one correspondence.

18. The backlight module as recited in claim 1, wherein the at least one electrostatic assembly is detachably connected to the back plate.

19. A backlight module, comprising:
a back plate;
at least one light plate fixed onto the back plate, wherein there is disposed at least one first rivet post on a side of the at least one light plate facing the back plate, wherein the at least one first rivet post penetrates the back plate and protrudes from a back side of the back plate; wherein there is disposed at least one second rivet post on the back side of the back plate, wherein the at least one second rivet post is arranged side by side with the at least one first rivet post; and
at least one electrostatic assembly, which is connected to both the at least one first rivet post and the at least one second rivet post, and conducts the at least one first rivet post and the at least one second rivet post with each other;
wherein the electrostatic assembly comprises:
a lower box, made of an insulating material, the lower box defining a through hole corresponding to each of the at least one first rivet post and the at least one second rivet post;
a top cover, made of an insulating material and fitted with the lower box to form a sealed cavity;
a positive conductive plate, which is arranged in the sealed cavity, fixed onto the lower box, and connected to the at least one first rivet post;
a negative conductive plate, which is arranged in the sealed cavity, fixed onto the lower box, and connected to the at least one second rivet post, wherein the positive conductive plate is electrically connected with the negative conductive plate; and
a light-emitting assembly, wherein one end of the light-emitting assembly is connected to the positive conductive plate, and wherein another end of the light-emitting assembly is connected to the negative conductive plate;
wherein the light-emitting assembly comprises: a conductive substrate with unconnected ends; and a plurality of light-emitting elements that are arranged at intervals on a surface of the conductive substrate;
wherein the lower box comprises a bottom plate and a fixing seat, wherein the positive conductive plate and the negative conductive plate are arranged on the bottom plate; wherein the fixing seat is arranged on a side of the bottom plate facing the top cover, and is disposed around the positive conductive plate and the negative conductive plate; wherein there is defined an insertion groove in the fixing seat, and wherein the insertion groove is disposed around the positive conductive plate and the negative conductive plate;
wherein the conductive substrate is inserted into the insertion groove, and wherein one end of the conductive substrate is connected to the positive conductive plate through a first lead, and wherein another end of the conductive substrate is connected to the negative conductive plate through a second lead.

20. A display device, comprising a display panel and a backlight module configured to provide backlight for the display panel; wherein the backlight module comprises a back plate and at least one light plate fixed onto the back plate, wherein there is disposed at least one first rivet post on a side of the at least one light plate facing the back plate, wherein the at least one first rivet post penetrates the back plate and protrudes from a back side of the back plate; wherein there is disposed at least one second rivet post on the back side of the back plate, wherein the at least one second rivet post is arranged side by side with the at least one first rivet post;
wherein the backlight module further comprises an electrostatic assembly, which is connected to both the at least one first rivet post and the at least one second rivet post, and conducts the at least one first rivet post and the at least one second rivet post with each other.
